(19) United States
(12) Patent Application Publication
(10) Pub. No.: US 2026/0328645 A1
(43) Pub. Date: Oct. 22, 2026

(54) APPARATUS FOR MEASURING A TELECENTRICITY OF AN OPTICAL IMAGING SYSTEM

(71) Applicant: Carl Zeiss SMT GmbH, Oberkochen (DE)

(72) Inventor: Daniel ENDRES, Koenigsbronn (DE)

(21) Appl. No.: 19/692,094

(22) Filed: May 29, 2026

Related U.S. Application Data
(63) Continuation of application No. PCT/EP2024/083810, filed on Nov. 27, 2024.

(30) Foreign Application Priority Data
Dec. 5, 2023 (DE) 10 2023 212 214.6

(51) Int. Cl. G01M 11/02

(52) U.S. Cl. CPC G01M 11/0221

(57) ABSTRACT

An intensity detector (28) of a telecentricity measuring apparatus includes multiple non-overlapping detection portions (42-1, 42-2) and is arranged offset from an image plane (16) of an imaging system to be measured. For at least two field points (18-1, 18-2) in the image plane, the intensity detector acquires angle-resolved intensity distributions (50) present at the field points using respective detection portions of the intensity detector. A movement device (30) sets different measurement positions (54) through changes in relative position between the intensity detector and the imaging system. The intensity distribution (50-2) of at least one of the field points before and after the change is acquired using differing non-overlapping detection portions of the intensity detector. An evaluation device (48) ascertains the telecentricity (68) of the imaging system at each of the at least two field points based on angle-resolved intensity distributions (50-1, 50-2) recorded at the measurement positions.

### CROSS REFERENCE TO RELATED APPLICATIONS

This is a Continuation of International Application PCT/EP2024/083810 which has an international filing date of Nov. 27, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application German Patent Application No. 10 2023 212 214.6 filed on Dec. 5, 2023.

### FIELD

The invention relates to an apparatus and a method for measuring a telecentricity of an optical imaging system, for example a projection lens of a microlithographic projection exposure apparatus.

### BACKGROUND

As is known, the determination of telecentricity serves to identify deviations from an ideal telecentricity behavior of an optical imaging system, i.e. telecentricity errors. In the case of an imaging system afflicted by a telecentricity error, the chief ray for a respective field point does not run parallel to the optical axis of the imaging system, as in the error-free case, but rather at a tilt with respect to the optical axis, the tilt angle representing a quantitative measure of the telecentricity error. In other words, the telecentricity describes an energy-weighted tilt of the ray cone of an optical imaging system about the focal point in the image or object plane. The telecentricity error is a 2-dimensional quantity which can be represented as two tilt angles in relation to the corresponding plane normal in the direction of two orthogonal base vectors in the corresponding plane. The telecentricity error can be field-point-dependent, i.e. depend on the lateral position of the focal point in the corresponding plane. The telecentricity of microlithographic projection lenses at the image plane has effects on the distortion in the lithography process due to 3D-effects in the photoresist.

One approach for determining a telecentricity error is to measure the energy centroid of the image of a respective field point in an xy-plane perpendicular to the optical axis at multiple measurement points that are displaced with respect to one another in the z-direction of the optical axis and to calculate the tilt angle trigonometrically therefrom. However, this is countered by the difficulty that the energy centroid of the image of a respective field point in the xy-plane, which depends on the z-position, can also vary on account of other optical aberrations with which imaging systems are typically afflicted, such as coma and Petzval field curvature.

To avoid this problem, U.S. Pat. No. 7,365,861 B2 proposes to carry out a wavefront measurement at different z-positions in the optical imaging system with a shearing interferometer and to calculate the telecentricity based on the Z2 and Z3 Zernike coefficients measured in the process. In the case of a shearing-interferometry-based measurement, a measuring unit composed of a diffraction grating and a detector unit arranged therebelow is arranged in the image plane of the optical imaging system. An interference pattern is generated on the detector unit for different measurement channels arranged at different field points by superimposing the +/−1st orders of diffraction generated at the diffraction grating on one of the zeroth orders of diffraction. The measuring unit is displaced incrementally in the xy-plane such that the phase distribution of the interference patterns changes. This is also referred to as “phase shifting”, wherein the displacement steps are so small that the measurement channels remain unchanged during the measurement, i.e. the detector portions assigned to the individual measurement channels do not change; only the phase of the recorded interference patterns changes. However, it has emerged that this measurement method does not supply sufficiently accurate measurement values for the telecentricity either. In addition, reference is made to document CN 114647154 A.

### SUMMARY

Objects addressed by the invention include providing an apparatus and a method of the type set forth at the outset, with which the aforementioned deficiencies are overcome and, preferably, the accuracy of the telecentricity measurement is improved.

According to one formulation of the invention, the aforementioned objects are addressed, for example, by a measuring apparatus for measuring a telecentricity of an optical imaging system. The measuring apparatus according to this formulation of the invention comprises an illumination device which is configured to irradiate an object plane of the optical imaging system with measurement radiation and an intensity detector which comprises multiple non-overlapping detection portions. The intensity detector is arranged offset from an image plane of the optical imaging system and, for at least two field points in the image plane, is configured to acquire angle-resolved intensity distributions present at the field points using a respective one of the detection portions of the intensity detector. Furthermore, the measuring apparatus according to the invention comprises a movement device which is configured to set different measurement positions by such a change in relative position between the intensity detector and the optical imaging system in at least one rigid body degree of freedom that the intensity distribution of at least one of the field points before and after the change in relative position can be acquired using two different ones of the non-overlapping detection portions of the intensity detector, and an evaluation device which is configured to ascertain the telecentricity of the optical imaging system at each of the at least two field points based on angle-resolved intensity distributions which are recorded at the different measurement positions.

According to one embodiment, the intensity detector can be part of a sensor head. Telecentricity is understood to mean an energy-weighted tilt of one or more ray cones, assigned to a respective field point, of the optical imaging system about the focal point in the image plane or the object plane. This is referred to as image-side or object-side telecentricity. In the present case, the telecentricity measurement preferably comprises image-side telecentricity.

The change in the relative position of the intensity detector with respect to the optical imaging system should be understood to mean that, for this purpose, the position of the intensity detector and/or the position of the optical imaging system is changed. In this document, the intensity distribution acquired by the intensity detector is also referred to as a pupil image. The intensity detector is arranged so far offset vis-à-vis the image plane of the optical imaging system that the angle-resolved intensity distributions present in the image plane, i.e. the pupil images assigned to the individual field points, are represented on the detection area of the detector.

The angle-resolved intensity distributions recorded at the different relative positions of the intensity detector are intensity distributions which are generated on the detector by the above-explained change in the relative position of the intensity detector with respect to the optical imaging system. The angle-resolved intensity distribution at a field point corresponds to the intensity distribution in the pupil of the optical imaging system. Consequently, the intensity detector is configured and arranged to acquire the intensity distribution in a pupil or a pupil distribution of the optical imaging system at the relevant field points of the image plane. In other words, the relative position of the intensity detector is changed such that the pupil distribution assigned to a specific field point is acquired by a different portion of the intensity detector after the change in position than before the change in position. In this case, the two portions are non-overlapping portions, i.e. separate portions, respectively, of the detection detector.

The acquisition according to the invention of angle-resolved intensity distributions at different field points in the image plane, i.e. the acquisition of pupil distributions assigned to the different field points, and the change in the relative position of the intensity detector such that the intensity distribution of one of the field points can be acquired by two different, non-overlapping portions of the intensity detector before and after the change in relative position allows the determination of the telecentricity with a high accuracy by mathematical evaluation of the intensity distributions acquired at the different relative positions. The aforementioned change in relative position allows the generation of sufficient redundancy in the measurements acquired by the intensity detector in order to enable the mathematical evaluation for determining the telecentricity.

In comparison with the above-mentioned ascertainment of the telecentricity based on a wavefront measurement in accordance with U.S. Pat. No. 7,365,861B2, in which the telecentricity is essentially equated with a wavefront tilt which corresponds only approximately to the energy-weighted tilt of the ray cone of an optical imaging system, the procedure according to the invention allows the direct determination of the energy-weighted tilt of the ray cone and hence the determination of the telecentricity with a higher accuracy.

In the case of the aforementioned shearing-interferometry-based wavefront measurement, intensity distributions are likewise recorded with a detector unit; however, as already explained above, these are not angle-resolved intensity distributions in the form of pupil distributions assigned to the field points present at the field points but interference patterns. Even if the +/−1st orders of diffraction were removed from these interference patterns by calculation, the resultant intensity distributions would still differ from the intensity distributions acquired according to the invention under changing relative positions of the intensity detector. This is already due to the fact that the displacement of the measurement unit that takes place during the wavefront measurement is only implemented in small steps that serve for phase shifting and are not large enough to acquire one of the field points by two different, non-overlapping portions of the intensity detector before and after the change in relative position.

Prior to the change in relative position, at least two different, non-overlapping detection portions of the intensity detector, in particular the aforementioned two different, non-overlapping detection portions of the intensity detector, serve according to one embodiment to measure the intensity distributions of different field points.

According to a further embodiment, the measuring apparatus is configured to form measurement channels through the optical imaging system which pass through the image plane at respectively one of the field points to be measured and which are incident on different detection portions of a detection area of the intensity detector, wherein the movement device is configured to change the relative position such that before and after the change in position, a specific detection portion is irradiated by measurement radiation from different measurement channels.

According to one embodiment variant, the measuring apparatus furthermore comprises a measurement mask which is arranged in the object plane and which has measurement structures for forming the measurement channels. In other words, the measurement mask comprises an assigned measurement structure, which forms a respective measurement channel, for each of the field points of the image plane to be measured. The measurement mask may optionally also be movable with a movement device, which may be designed analogously to the movement device of the intensity detector.

According to a further embodiment, the measuring apparatus is configured to align the detector and optionally the measurement mask in all rigid-body degrees of freedom with respect to the image and object planes. This can be implemented by an external measuring system or a wavefront or intensity measurement.

According to one embodiment variant, in the case of more than two measurement masks, the distances of these measurement masks can be arranged on an equidistant grid in order to capture identical measurement channels in the optical imaging system in the case of displacements by integer multiples of these distances in the object plane or image plane and/or in the case of appropriately chosen rotations relative to the optical imaging system.

According to one embodiment variant, it is possible to use fewer measurement masks than measurement channels of the optical imaging system in order to prevent superposition of the intensity images on the intensity detector. The remaining measurement channels can be realized by serial measurements with different displacements and/or rotations of the intensity detector and of the measurement masks with respect to the optical imaging system.

According to a further embodiment, the change in the relative position comprises a relative translational movement of the intensity detector in relation to the optical imaging system in a direction transverse or orthogonal to an optical axis of the optical imaging system, which is also referred to as “lateral direction” in this document.

According to a further embodiment, the change in relative position comprises a relative translational movement of the measurement mask arranged in the object plane, in relation to the optical imaging system in a direction transverse to an optical axis of the optical imaging system. This can be implemented in a manner scaled by the imaging scale of the optical imaging system, in accordance with the relative translational movement of the intensity detector.

According to a further embodiment, the position of the intensity detector and optionally the position of the measurement mask are positionable through an external measuring system or via a wavefront-based and/or intensity-based alignment with respect to the image plane, or optionally with respect to the object plane, of the optical imaging system.

According to a further embodiment, the measuring apparatus is configured to form measurement channels through the optical imaging system which pass through the image plane at respectively one of the field points to be measured, wherein the change in relative position comprises a relative translational movement of the intensity detector in relation to the optical imaging system in a lateral direction with respect to an optical axis of the optical imaging system by at least a spacing between two adjacent measurement channels. This preferably relates to the distance between the two adjacent measurement channels in the image plane.

According to one embodiment variant, the evaluation device is configured to ascertain the telecentricity of the optical imaging system based on angle-resolved intensity distributions that are recorded at three different measurement positions which differ in relative displacement of the intensity detector with respect to the optical imaging system along a translational degree of freedom.

According to a further embodiment, the change in relative position comprises a relative rotational movement of the intensity detector in relation to the optical imaging system about an axis of rotation aligned with the direction of the optical axis.

The relative translational movement or the relative rotational movement should be understood to mean a translational movement or rotational movement of the optical imaging system and/or of the sensor element. The lateral direction to the optical axis should be understood to mean a direction which is aligned perpendicular to the optical axis or deviates from the perpendicular direction by up to 45°, in particular up to 30° or up to 10°. The alignment of the axis of rotation in the direction of the optical axis should be understood to mean an exactly parallel alignment to the optical axis or an alignment deviating therefrom by up to 45°, in particular up to 30° or up to 10°.

According to a further embodiment, the evaluation device is configured to determine a respective associated pupil image position from the recorded angle-resolved intensity distributions for each of the relative positions at all measured field points.

According to one embodiment variant, the respective determined pupil image position comprises a displacement value of the relevant pupil image vis-à-vis an associated standard pupil image, which would be present in the absence of telecentricity, in at least one coordinate direction.

According to a further embodiment variant, the evaluation device is configured to determine the displacement values by evaluating a system of equations containing the determined pupil image positions.

According to a further embodiment variant, the evaluation device is configured to determine the determination of the pupil image positions with sub-pixel accuracy respectively in relation to a pixel resolution of the intensity detector.

According to a further embodiment variant, the evaluation device is configured to bring about the determination of the pupil image positions through an edge fit of the recorded intensity distributions.

According to a further embodiment, the respective edge fit is implemented based on intensity distributions which were averaged over different measurement positions of the intensity detector. The measurement positions can be displaced by a fraction, e.g. half, of a grating period of the diffraction grating. Alternatively, the measurement positions can also be displaced by more than half the grating period of the diffraction grating, for example by one, one and a half or two grating periods of the diffraction grating.

According to a further embodiment, the evaluation device is configured to convert the determined pupil image positions into telecentricity angles of the optical imaging system. In this case, the pupil image positions are converted into ray cone angles in the substrate medium by considering conical sections, and the telecentricity angles of the optical imaging system are determined therefrom.

According to a further embodiment, the evaluation device is configured to determine the numerical aperture at each of the field points from the recorded angle-resolved intensity distributions and to take this into account when determining the telecentricity. In other words: An NA field profile is determined. To determine the numerical aperture, a pupil radius is determined for each of the relative positions at each of the field points. The displacement values of the pupil image position depend on the numerical aperture. By determining the numerical aperture, this influence can be taken into account when ascertaining the telecentricity. In an alternative embodiment, it is ensured that the intensity distributions are measured with a full NA. In this case, the NA field profile need not be measured since it is already known in advance.

According to a further embodiment, the measuring apparatus is configured to measure the measurement channels partially in series by displacing the intensity detector and optionally the measurement mask. A higher lateral resolution than would be permitted by the intensity detector without overlapping pupil images can thus be achieved.

According to one embodiment, an NA stop installed in the microlithographic projection exposure lens in a pupil plane can be partially closed in a defined manner in order to determine the telecentricity for corresponding applications in a manner analogous to the measurement with a full NA.

According to one embodiment, the optical imaging system is a projection lens of a microlithographic projection exposure apparatus, which is configured for DUV (“Deep UltraViolet”) or EUV (“Extreme UltraViolet”) microlithography, for example.

Furthermore, according to the invention, provision is made for a microlithographic projection exposure apparatus comprising a projection lens and a measuring arrangement according to any of the preceding embodiments or embodiment variants for measuring a telecentricity of the projection lens.

Furthermore, according to a further formulation, the aforementioned objects are addressed, for example, by a method for measuring a telecentricity of an optical imaging system. The method comprises irradiating an object plane of the optical imaging system with measurement radiation, arranging an intensity detector comprising multiple non-overlapping detection portions in a plane offset from an image plane of the optical imaging system and acquiring angle-resolved intensity distributions which are present at at least two field points in the image plane using a respective detection portion of the intensity detector. The method also comprises changing a relative position of the intensity detector with respect to the optical imaging system in at least one rigid body degree of freedom in order to set different measurement positions and acquiring the intensity distribution of at least one of the field points before and after the change in relative position using two different ones of the non-overlapping detection portions of the intensity detector, and ascertaining the telecentricity of the optical imaging system based on angle-resolved intensity distributions, recorded at the different measurement positions, at each of the at least two field points.

According to one embodiment of the method according to the invention, a relative position of the intensity detector and of the measurement mask with respect to the optical imaging system is changed in at least one rigid-body degree of freedom for the purpose of setting the different measurement positions. Thereupon, the intensity distribution of at least one of the field points is acquired before and after the change in relative position using two different non-overlapping detection portions of the intensity detector.

According to one embodiment of the method according to the invention, the intensity detector is adjusted vis-à-vis the optical imaging system before the angle-resolved intensity distributions are acquired, wherein a diffraction grating is arranged in the image plane, and hence a wavefront measurement of the optical imaging system is carried out with the intensity detector. Based on the wavefront measurement, the intensity detector can in turn be adjusted in the direction of the optical axis of the optical imaging system, i.e. with respect to the focus setting, and/or transversely thereto. The adjustment can be carried out after each change in relative position in particular, i.e. before the acquisition of the intensity distributions following the respective change in relative position.

The features specified with respect to the abovementioned embodiments, exemplary embodiments or embodiment variants, etc., of the measuring apparatus according to the invention can be correspondingly applied to the measurement method according to the invention, and vice versa. These and other features of the embodiments according to the invention are explained in the description of the figures and in the claims. The individual features may be implemented either separately or in combination as embodiments of the invention. Furthermore, they may describe advantageous embodiments that are independently protectable and protection for which is claimed only during or after pendency of the application, as the case may be.

### BRIEF DESCRIPTION OF THE DRAWINGS

The aforementioned features and further advantageous features of the invention will be illustrated in the following detailed description of exemplary embodiments according to the invention or of embodiments or variant embodiments with reference to the attached schematic drawings. In detail:

FIG. 1 shows an exemplary embodiment of a measuring apparatus for measuring a telecentricity of an optical imaging system at a multiplicity of field points in an image plane of the optical imaging system, having a sensor head in the form of an intensity detector,

FIG. 2 shows an enlarged illustration of the beam path in the region of a field point of a sensor head in the image plane of the optical imaging system,

FIG. 3 shows an alternative exemplary embodiment of the sensor head,

FIG. 4 shows a first exemplary embodiment, simplified to one dimension, of a method for operating the measuring apparatus according to FIG. 1 for measuring telecentricity,

FIG. 5 shows a second exemplary embodiment, simplified to one dimension, of the method for operating the measuring apparatus according to FIG. 1 for measuring telecentricity, and

FIG. 6 shows an exemplary embodiment of a projection exposure apparatus comprising a projection lens and a measuring apparatus according to FIG. 1, integrated in the projection exposure apparatus, for measuring the telecentricity of the projection lens.

### DETAILED DESCRIPTION

In the exemplary embodiments or embodiments or embodiment variants described below, elements that are functionally or structurally similar to one another are provided with the same or similar reference signs as far as possible. Therefore, for understanding the features of the individual elements of a specific exemplary embodiment, reference should be made to the description of other exemplary embodiments or the general description of the invention.

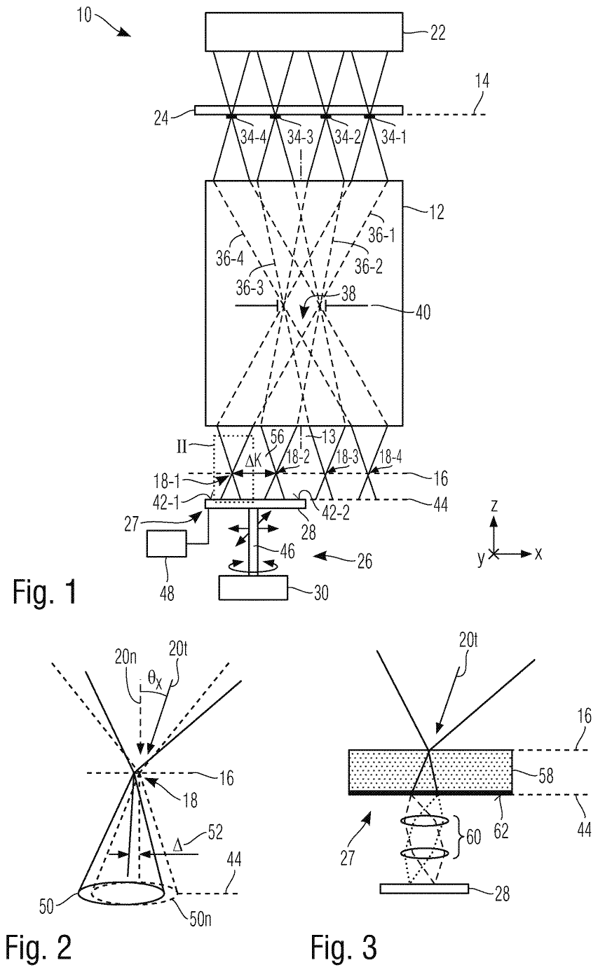

In order to facilitate the description, a Cartesian xyz-coordinate system is indicated in the drawing, from which system the respective positional relationship of the components illustrated in the figures is evident. In FIG. 1, the y-direction runs perpendicularly to the plane of the drawing into this plane, the x-direction runs toward the right, and the z-direction runs upward.

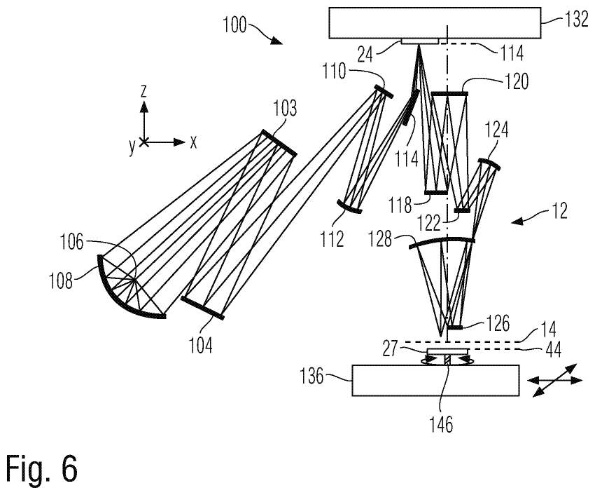

FIG. 1 illustrates an exemplary embodiment of a measuring apparatus 10 for measuring a telecentricity of an optical imaging system 12. The optical imaging system 12 can be a microlithographic imaging system, for example an optical imaging system 12 for a microlithographic projection exposure apparatus, in particular a projection lens of a microlithographic projection exposure apparatus. Alternatively, the optical imaging system 12 can also be a module of an illumination system of a microlithographic projection exposure apparatus or a module of a wafer inspection apparatus, etc. An exemplary embodiment 100 of a microlithographic projection exposure apparatus is illustrated in FIG. 6.

The optical imaging system 12 has an optical axis 13, serves for imaging structures, for example structures of a lithography mask, from an object plane 14 into an image plane 16 and can be designed for exposure radiation of different wavelengths, for example for DUV radiation having a wavelength of about 248 nm or about 193 nm or for EUV radiation. Within the scope of this document, EUV radiation should be understood to mean electromagnetic radiation with a wavelength of less than 100 nm, in particular a wavelength of about 13.5 nm or about 6.7 nm.

As already mentioned above, the measuring apparatus 10 serves to measure the telecentricity of the optical imaging system 12. Here, telecentricity should be understood to mean a field distribution of a telecentricity error in the image plane 16 of the optical imaging system 12. In the case of an imaging system afflicted by a telecentricity error, the chief ray for a respective field point does not run parallel to the optical axis of the imaging system, as in the error-free case, but rather at a tilt with respect to this optical axis, the tilt angle representing a quantitative measure of the telecentricity error. In other words, the telecentricity describes an energy-weighted tilt of the ray cone of an optical imaging system about the focal point in the image or object plane. For an exemplary field point 18 in the image plane 16, FIG. 2 illustrates such a chief ray 20t which is afflicted with a telecentricity error and tilted by the tilt angle θx in the xz-plane vis-à-vis a standard chief ray 20n (without telecentricity error) which runs parallel to the optical axis of the imaging system 12.

The measuring apparatus 10 comprises, on the input side of the optical imaging system 12, an illumination device 22 and a measurement mask 24 and, on the output side of the imaging system 12, a sensor module 26 which comprises a sensor head 27, here in the form of an intensity detector 28, a movement device 30 for changing a relative position of the intensity detector 28 with respect to the optical imaging system 12 and an evaluation device 32.

In FIG. 1, the measurement mask 24 is illustrated as an element operated in transmission, but it can also be operated in reflection according to an alternative embodiment. The illumination device 22 is configured to generate measurement radiation 32 and to irradiate the measurement mask 24 therewith. According to one embodiment, the wavelength of the measurement radiation 32 can be the operating wavelength of the optical imaging system 12 to be tested or be located in a similar wavelength range. Should the optical imaging system 12 be embodied as a projection lens of a microlithographic projection exposure apparatus, the wavelength of the measurement radiation 32 can thus be located approximately in the DUV or EUV wavelength range.

The measurement mask 24 comprises a two-dimensional point grid of measurement structures 34 (cf. measurement structures 34-1 to 34-4 according to FIG. 1). Each of these is configured as a periodic structure, for instance a checkerboard structure, and serves to form measurement channels 36 through the optical imaging system 12, as illustrated in FIG. 1 based on the measurement channels 36-1 to 36-4. Proceeding from the individual measurement structures 34-1 to 34-4, the rays contained in the measurement channels 36-1 to 36-4 pass through the optical imaging system 12 along different beam paths, in this case passing through at least one pupil plane in which the maximum angular space is limited by geometric restrictions (e.g. mechanical stop 40). This maximum angular space defines the pupil 38 of the optical imaging system 12. In this context, pupil 38 refers to the area in the pupil plane through which the respective rays of all measurement channels 36-1 to 36-4 pass, i.e. the rays of the different measurement channels 36-1 to 36-4 each pass the same area of the pupil plane. The rays that pass through the pupil 38, i.e. the rays not absorbed by the stop 40, continue to propagate and converge respectively at field points 18-1 to 18-4 to be measured in the image plane 16, pass through these field points respectively and are incident on different, non-overlapping detection portions 42 of a detection area of the intensity detector 28. The respectively adjacent field points 18-1 to 18-4 have a spacing ΔK (reference sign 56). This is the distance between the corresponding adjacent measurement channels 36 in the image plane 16.

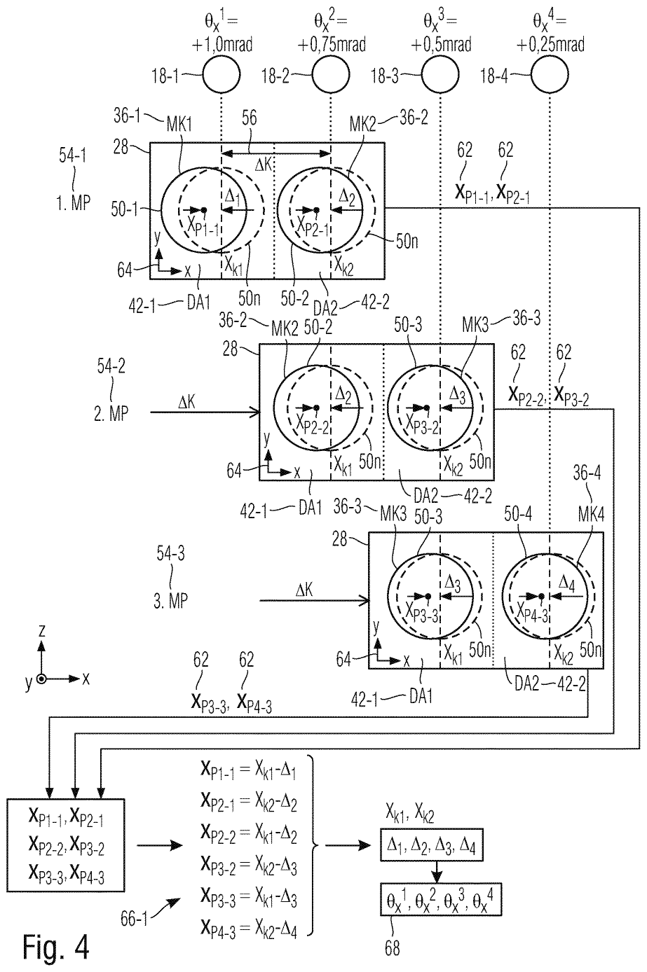

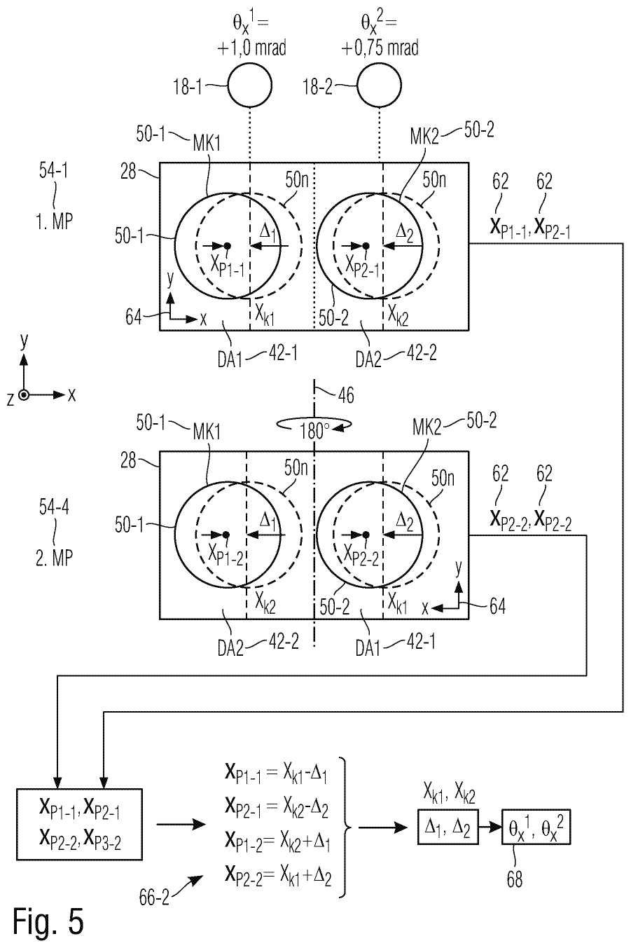

In the embodiment illustrated in FIG. 1, the intensity detector 28 is illustrated with only two detection portions 42-1 and 42-2 that adjoin each other in the x-direction. In this embodiment, the intensity detector 28 serves for partially serial measurement of the measurement channels, i.e. it is possible, for instance, to measure the measurement channels 36-1 and 36-2 in a first measurement and then the measurement channels 36-3 and 36-4 in a second measurement. In FIGS. 4 and 5, the detection portions 42-1 and 42-2 are also denoted by the abbreviations DA1 and DA2. According to further embodiments, not illustrated in the drawing, the intensity detector 28 can also have a greater number of detection portions 42 that adjoin one another in the x-direction; in particular it may have as many detection portions as there are measurement channels 36. Furthermore, the intensity detector 28 may have further detection portions 42 that adjoin one another in the y-direction, i.e. it may comprise a two-dimensional grid of detection portions 42.

The intensity detector 28 is arranged in a detection plane 44 that is offset in a defined manner with respect to the image plane 16 and that, in the present case, is located below the image plane 16, to be precise, such that the intensity distribution found in the pupil 38 of the optical imaging system 12 and assigned to the corresponding field point 18-1 or 18-2 is respectively present at the detection portions 42-1 and 42-2. These pupil intensity distributions correspond to the angle-resolved intensity distributions at the field points 18-1 and 18-2 in the image plane 16 and are also referred to as pupil images 50 in this document (cf. FIG. 2). In other words: The intensity detector 28 is arranged such that the respective angle-resolved intensity distribution in question at the field points 18-1 and 18-2 can be acquired respectively with the detection portions 42-1 and 42-2.

The intensity detector 28 is fastened to the aforementioned movement device 30, as a result of which the intensity detector 28 can be displaced in the xy-plane, i.e. in a lateral direction, with respect to the optical axis 13 of the optical imaging system 12 arranged in the z-direction and/or be rotated about an axis of rotation 46 parallel to the optical axis 13. Alternatively, the optical imaging system 12, optionally together with the measurement mask 24, can also be mounted in a correspondingly displaceable and/or rotatable manner. Furthermore, the position of the intensity detector 28 can also be displaced with respect to the optical imaging system 12, while at the same time the position of the measurement mask 24 is updated in accordance with the imaging scale of the optical imaging system 12 such that the assignment of the measurement structures 34 to the field points 18 is retained.

Importantly, it is possible to change the relative position of the intensity detector 28 with respect to the optical imaging system, specifically by carrying out a relative translational movement in a lateral direction with respect to the optical axis of the optical imaging system 12 and/or by carrying out a relative rotational movement about an axis of rotation aligned in the direction of the optical axis. As a result of the corresponding change in relative position of the intensity detector 28, it is possible to set different measurement positions 54, of which three measurement positions (1.MP, 2.MP and 3.MP) set by displacing the intensity detector 28 in the x-direction are elucidated in FIG. 4, which is explained in more detail below, and two measurement positions (1.MP and 2.MP) set by rotating the intensity detector 28 through 180° are elucidated in FIG. 4, which is likewise explained in more detail below.

Furthermore, the measuring apparatus 10 comprises an evaluation device 48, which is configured to ascertain the telecentricity of the optical imaging system 12 at the various field points 18 based on pupil images 50 recorded at the different relative positions of the intensity detector 28 for different field points 18, as explained in more detail below.

FIG. 2 illustrates the beam path when recording the pupil image 50 for an exemplary field point 18 in the image plane 16 in the presence of a telecentricity error, in which the chief ray 20t is tilted by the tilt angle θx vis-à-vis the standard chief ray 20n without telecentricity error. In this case, the measured pupil image 50 is displaced by a displacement value Δ (reference sign 52) vis-à-vis a standard pupil image 50n, which is illustrated by broken lines and which could be measured in the absence of telecentricity errors.

FIG. 3 illustrates an alternative embodiment of the sensor head 27, which can be used instead of the sensor head according to FIG. 1 comprising only the intensity detector 28. The sensor head according to FIG. 3 comprises a substrate 58, the top side of which is arranged in the image plane 16, an imaging optics unit 60 and the intensity detector 28. A wavelength-converting layer 62 or a quantum converter is applied to an underside of the substrate 58, which represents the detection plane 44 in which the pupil image 50 to be recorded is generated. The layer 62 converts the wavelength of the measurement radiation 32 into a detection wavelength of the intensity detector 28. For example, the wavelength-converting layer 62 is configured to convert EUV radiation into visible radiation. Here, the imaging optics unit 60 is embodied in the form of a relay lens and serves to image the pupil image present in the detection plane 44 onto the intensity detector 28. In the cases in which a change in relative position of the intensity detector 28 is referred to with reference to the sensor head according to FIG. 1 in this document, the described relationship can be transferred to the sensor head 27 according to FIG. 3, wherein the entire sensor head 27 including the substrate 58, the imaging optics unit 60 and the intensity detector 28 experiences the change in relative position.

FIG. 4 illustrates a first exemplary embodiment of a method for measuring the telecentricity of the optical imaging system 12 with the measuring apparatus 10 according to FIG. 1. In this method, the intensity detector 28 is arranged in three different measurement positions 54-1 (1.MP), 54-2 (2.MP) and 54-3 (3.MP). The pupil images 50 present at the detection portions 42-1 (DA1) and 42-2 (DA2) are captured in each measurement position, and an associated pupil image position 62 on the intensity detector 28, i.e. in the coordinate system 64 of the intensity detector 28, is determined for each pupil image 50.

Specifically, the intensity detector is situated in the first measurement position 54-1 at the position below the field points 18-1 and 18-2 as illustrated in FIG. 1, i.e. the detection portions DA1 and DA2 are irradiated by the measurement channels 36-1 and 36-2.

For the telecentricity at the field points 18-1, 18-2, 18-3 and 18-4, the tilt angles θx1=+1.0 mrad, θx2=+0.75 mrad, θx3=+0.5 mrad and θx4=0.25 mrad are set in FIG. 1 for illustrative purposes. In the first measurement position 54-1, a pupil image 50-1 arises at the detection portion DA1; this pupil image is assigned to the first field point 18-1 or to the first measurement channel MK1 and is displaced by Δ1 on account of the tilt angle θx1 vis-à-vis the corresponding standard pupil image 50n, the center of which is at the x-coordinate xk1 in the coordinate system 64 of the intensity detector 28. A pupil image 50-2 arises at the detection portion DA2; this pupil image is assigned to the second field point 18-2 or to the second measurement channel MK2 and is displaced by Δ2 on account of the tilt angle θx2 vis-à-vis the corresponding standard pupil image 50n, the center of which is at the x-coordinate xk2 in the coordinate system 64 of the intensity detector 28.

From pupil images 50-1 and 50-2 captured in the first measurement position 54-1, the evaluation device 48 ascertains the respective pupil image positions 62; in the present case, these are the x-coordinates xp1-1 and xp2-1 of the centers of the pupil images 50-1 and 50-2 in the coordinate system 64 of the intensity detector 28. In this case, the pupil image positions 62 are determined respectively through an edge fit of the captured pupil images 50 and with sub-pixel accuracy in relation to the pixel resolution of the intensity detector 28.

In addition to the intensity detector 28, the sensor head according to FIG. 1 can furthermore comprise a diffraction grating arranged in the image plane 16 according to an alternative embodiment of the measuring apparatus 10. In the respective detector portions 42, the intensity detector at the respective measurement position 54 does not in this case record the relevant pupil image 50 or the angle-resolved intensity distribution present at the relevant field point 18. Instead, a respective interference pattern formed by superimposing the zeroth order of diffraction, which corresponds to the relevant pupil image 50, on the +/−1st order of diffraction is generated in the respective detector portions 42. In this embodiment, a multiplicity of interference patterns are recorded, each with a slightly shifted phase, and the interference patterns are then averaged. Thus, approximately ten interference patterns can be recorded with a diffraction grating displaced respectively by λ/10. In the case of two-dimensional diffraction gratings, corresponding lateral displacements should be chosen such that the averaged image corresponds to the zeroth order of diffraction.

By averaging the interference patterns, it is possible to ascertain the DC component which substantially corresponds to the pupil image 50. In other words, a special method is applied when use is made of a diffraction grating in the image plane 16; this method is used to remove the +/−1st orders of diffraction from the recorded intensity distribution by calculation, and only then are the angle-resolved intensity distributions, which are in the form of the pupil images 50 and present at the field points 18, ascertained. Then, as described above, an edge fit is used to initially determine the x-coordinates xp1-1 and xp2-1 of the pupil image positions 62 from the pupil images 50 ascertained thus.

After the pupil images 50 have been recorded in the first measurement position 54-1, the intensity detector 28 is displaced in the x-direction by the distance ΔK between the measurement channels 36 and thus displaced into the second measurement position 54-2. Here, the pupil image 50-2 assigned to the second measurement channel MK2 is present at the detector portion DA1. That is to say, the pupil image 50-2 can be captured with two different detection portions in the two measurement positions 54-1 and 54-2, specifically by the detection portion DA2 in the first measurement position 54-1 and the detection portion DA1 in the second measurement position 54-2.

The pupil image 50-3 assigned to the third measurement channel MK3 is present at the second detection portion DA2 in the second measurement position 54-2. As in the first measurement position 54-1, the pupil image 52-2 is also displaced in the second measurement position 54-2 by Δ2 vis-à-vis the standard pupil image 50n, the center of which is at the x-coordinate xk1 in the coordinate system 64 of the intensity detector 28. By contrast, in the second measurement position 54-2 and on account of the tilt angle θx3, the pupil image 52-3 is displaced by Δ3 vis-à-vis the corresponding standard pupil image 50n, the center of which is at the x-coordinate xk2 in the coordinate system 64 of the intensity detector 28. From pupil images 50-2 and 50-3 captured in the second measurement position 54-2, the evaluation device 48 uses an edge fit to ascertain the respective pupil image positions 62; in the present case, these are the x-coordinates xp2-2 and xp3-2 of the centers of the pupil images 50-2 and 50-3 in the coordinate system 64 of the intensity detector 28.

After the pupil images 50 have been recorded in the second measurement position 54-2, the intensity detector 28 is displaced yet again in the x-direction by the distance ΔK between the measurement channels 36 and thus displaced into the third measurement position 54-3. Here, the pupil image 50-3 assigned to the third measurement channel MK3 is present at the detector portion DA1. The pupil image 50-4 assigned to the fourth measurement channel MK4 is present at the second detection portion DA2 in the third measurement position 54-3. As in the second measurement position 54-2, the pupil image 52-3 is also displaced in the third measurement position 54-3 by Δ3 vis-à-vis the standard pupil image 50n, the center of which is at the x-coordinate xk1 in the coordinate system 64 of the intensity detector 28. By contrast, in the third measurement position 54-3 and on account of the tilt angle θx4, the pupil image 52-4 is displaced by Δ4 vis-à-vis the corresponding standard pupil image 50n, the center of which is at the x-coordinate xk2 in the coordinate system 64 of the intensity detector 28. From pupil images 50-3 and 50-4 captured in the third measurement position 54-3, the evaluation device 48 uses an edge fit to ascertain the respective pupil image positions 62; in the present case, these are the x-coordinates xp3-3 and xp4-3 of the centers of the pupil images 50-3 and 50-4 in the coordinate system 64 of the intensity detector 28.

The following relationships apply to the x-coordinates xp1-1 and xp2-1 ascertained in the first measurement position 54-1: xp1-1=xk1−Δ1 and xp2-1=xk2−Δ2; analogous relationships apply to x-coordinates xₚ₂₋₂, xₚ₃₋₂, xₚ₃₋₃ and xₚ₄₋₃ ascertained in the second measurement position 54-2 and the third measurement position 54-3. The following equation system 66-1 can thus be set up:

xₚ₁₋₁=xₖ₁−Δ₁ 1)

xₚ₂₋₁=xₖ₂−Δ₂ 2)

xₚ₂₋₂=xₖ₁−Δ₂ 3)

xₚ₃₋₂=xₖ₂−Δ₃ 4)

xₚ₃₋₃=xₖ₁−Δ₃ 5)

xₚ₄₋₃=xₖ₂−Δ₄ 6)

This system of equations comprising six equations has six unknowns: xₖ₁, xₖ₂, Δ₁, Δ₂, Δ₃ and Δ₄, and these can be ascertained by solving the system of equations. This is carried out in the evaluation device 48. Furthermore, by considering appropriate conical sections, the evaluation device 48 converts the displacement values Δ₁, Δ₂, Δ₃ and Δ₄ determined therewith into the relevant tilt angles θₓ¹, θₓ², θₓ³ and θₓ⁴ (also referred to as telecentricity angles) and thus ascertains a telecentricity field profile 68 in the x-coordinate direction at the field points 18-1, 18-2, 18-3 and 18-4. According to a further embodiment, the measuring apparatus 10 is configured to ascertain the telecentricity field profile in two-dimensions, i.e. in the x-and y-directions, i.e. the tilt angles θₓ and θ_{y} are ascertained at the various field points 18.

The relationship between a displacement value Δ of the pupil image and the associated telecentricity angle θ depends on the numerical aperture (NA) of the optical imaging system 12. According to one embodiment, the numerical aperture is therefore determined from the recorded pupil images 50 at the various field points 18 and taken into account when determining the telecentricity angle θ. According to a further embodiment, it is ensured that the pupil images 50 are measured with a full numerical aperture. In this case, the numerical aperture is known in advance, and therefore the NA field profile need not be measured.

FIG. 5 illustrates a second exemplary embodiment of a method for measuring the telecentricity of the optical imaging system 12 with the measuring apparatus 10 according to FIG. 1. In this method, the intensity detector 28 is arranged in two different measurement positions 54-1 (1.MP) and 54-4 (2.MP). The first measurement position 54-1 corresponds to the first measurement position according to FIG. 4, while the second measurement position 54-4 is not implemented by a displacement of the intensity detector 28 like in FIG. 4 but by a 180° rotation of the intensity detector 28 about the axis of rotation 46.

Analogously to the measurement method according to FIG. 4, in the measurement method according to FIG. 4 the pupil images 50 present at the detection portions 42-1 (DA1) and 42-2 (DA2) are captured in each of the measurement positions 54-1 and 54-4, and an associated pupil image position 62 on the intensity detector 28, i.e. in the coordinate system 64 of the intensity detector 28, is determined for each pupil image 50. From pupil images 50-1 and 50-2 captured in the first measurement position 54-1, the evaluation device 48 thus ascertains the respective pupil image positions 62; in the present case, these are the x-coordinates xp1-1 and xp2-1 of the centers of the pupil images 50-1 and 50-2 in the coordinate system 64 of the intensity detector 28.

In the second measurement position 54-4, the pupil image 50-1 assigned to the first measurement channel MK1 is present at the detector portion DA2, and the pupil image 50-2 assigned to the second measurement channel MK2 is present at the detector portion DA1. That is to say, the pupil image 50-1 can be captured with two different detection portions in the two measurement positions 54-1 and 54-4 specifically by the detection portion DA1 in the first measurement position 54-1 and the detection portion DA2 in the second measurement position 54-4. The same applies to the pupil image 50-2. From pupil images 50-1 and 50-2 captured in the second measurement position 54-4, the evaluation device 48 thus ascertains the respective pupil image positions 62; in the present case, these are the x-coordinates xp2-2 and xp2-2 of the centers of the pupil images 50-1 and 50-2 in the coordinate system 64 of the intensity detector 28.

The following equation system 66-2 can be set up from the relationships which apply to the x-coordinates ascertained in the measurement positions 54-1 and 54-4:

xₚ₁₋₁=xₖ₁−Δ₁ 1)

xₚ₂₋₁=xₖ₂−Δ₂ 2)

xₚ₁₋₂=xₖ₂+Δ₁ 3)

xₚ₂₋₂=xₖ₁+Δ₂ 4)

This system of equations comprising four equations has four unknowns: xₖ₁, xₖ₂, Δ₁, Δ₂, and these can be ascertained by solving the system of equations. This is carried out in the evaluation device 48. Furthermore, by considering appropriate conical sections, the evaluation device 48 converts the displacement values Δ₁ and Δ₂ determined therewith into the relevant tilt angles θₓ¹ and θₓ² (also referred to as telecentricity angles) and thus ascertains the telecentricity field profile 68 in the x-coordinate direction at the field points 18-1 and 18-2.

In a simplified illustration, FIG. 6 elucidates an exemplary embodiment of a projection exposure apparatus 100 having an optical imaging system 12 in the form of a projection lens. In order to measure the projection lens 12, the measuring apparatus 10 according to FIG. 1 is integrated in the projection exposure apparatus 100.

The microlithographic projection exposure apparatus 100 illustrated in FIG. 6 is designed for operation with EUV exposure radiation. However, the present invention is not limited to application in such an apparatus but may also be applied when measuring projection exposure apparatuses with different operating wavelengths, for example operating wavelengths in the VUV (“Vacuum UltraViolet”) or DUV range.

According to the exemplary embodiment of FIG. 6, the projection exposure apparatus 100 comprises a field facet mirror 103 and a pupil facet mirror 104. The light from a light source unit comprising a plasma light source 106 and a collector mirror 108 is directed to the field facet mirror 103. A first telescope mirror 110 and a second telescope mirror 112 are arranged downstream of the pupil facet mirror 104 in the light path. Arranged downstream in the light path is a deflection mirror 114, which directs the radiation incident thereon to an object field in the object plane 14 of the projection lens 12, which comprises six mirrors 118, 120, 122, 124, 126 and 128.

The projection exposure apparatus 100 furthermore comprises a mask stage 132 and a wafer stage 136 for holding a wafer to be exposed during exposure operation of the projection exposure apparatus 100. The measurement mask 24 of the measuring apparatus 10 is arranged on the mask table 132. The sensor head 27 having the intensity detector 28 is integrated into the wafer stage 136. In this case, the wafer stage 136 is movable in the x-and y-directions. The sensor head 27 is fastened to the wafer stage with a rotation device 146 that is configured to rotate about the axis of rotation 46. The movement mechanism of the wafer stage 136 in conjunction with the rotation device thus serves as the movement device 30 according to FIG. 1.

The above description of exemplary embodiment examples, embodiments or embodiment variants should be understood to be by way of example. The disclosure effected thereby firstly enables a person skilled in the art to understand the present invention and the advantages associated therewith, and secondly encompasses alterations and modifications of the described structures and methods that would be within the abilities and understanding of a person skilled in the art. Therefore, all such alterations and modifications, insofar as they fall within the scope of the invention in accordance with the definition in the accompanying claims, and equivalents are intended to be covered by the protection of the claims.

### LIST OF REFERENCE SIGNS

10 Measuring apparatus
12 Optical imaging system
13 Optical axis
14 Object plane
16 Image plane
18 Field point
20t Chief ray with telecentricity error
20n Standard chief ray
22 Illumination device
24 Measurement mask
26 Sensor module
27 Sensor head
28 Intensity detector
30 Movement device
32 Measurement radiation
34 Measurement structures
36 Measurement channels
38 Pupil
40 Stop
42 Detection portions
44 Detection plane
46 Axis of rotation
48 Evaluation device
50 Pupil image
50n Standard pupil image
52 Displacement value Δ
54 Measurement positions
56 Distance between two adjacent measurement channels
58 Substrate
60 Imaging optics unit
62 Pupil image position
64 Coordinate system of the intensity detector
66-1, 66-2 System of equations
68 Telecentricity field profile
100 Microlithographic projection exposure apparatus
103 Field facet mirror
104 Pupil facet mirror
106 Plasma light source
108 Collector mirror
110 First telescope mirror
112 Second telescope mirror
114 Deflection mirror
118, 120, 122, 124, 128 Mirrors of the projection lens
132 Mask stage
136 Wafer stage
146 Rotation device

What is claimed is:

1. A measuring apparatus for measuring a telecentricity of an optical imaging system, comprising:
an illumination device configured to irradiate an object plane of the optical imaging system with measurement radiation,
an intensity detector which comprises multiple non-overlapping detection portions, which is arranged offset from an image plane of the optical imaging system and which, for at least two field points in the image plane, is configured to acquire angle-resolved intensity distributions present at the field points from respective ones of the detection portions of the intensity detector,
a movement device which is configured to set different measurement positions, through a change in relative position between the intensity detector and the optical imaging system in at least one rigid body degree of freedom, that the intensity distribution of at least one of the field points before and after the change in relative position can be acquired from two different ones of the non-overlapping detection portions of the intensity detector, and
an evaluation device which is configured to ascertain the telecentricity of the optical imaging system at each of the at least two field points based on angle-resolved intensity distributions which are recorded at the different measurement positions.

2. The measuring apparatus as claimed in claim 1,
wherein prior to the change in relative position, the two different, non-overlapping detection portions of the intensity detector measure the intensity distributions of different field points.

3. The measuring apparatus as claimed in claim 1,
configured to form measurement channels through the optical imaging system which pass through the image plane at respective ones of the field points to be measured and which are incident on different detection portions of a detection area of the intensity detector, wherein the movement device is configured to change the relative position such that before and after the change in relative position, a specific detection portion is irradiated by measurement radiation from different measurement channels.

4. The measuring apparatus as claimed in claim 3,
further comprising a measurement mask which is arranged in the object plane and which has measurement structures for forming the measurement channels.

5. The measuring apparatus as claimed in claim 1,
wherein the change in relative position comprises a relative translational movement of the intensity detector in relation to the optical imaging system in a direction transverse to an optical axis of the optical imaging system.

6. The measuring apparatus as claimed in claim 1,
wherein the intensity detector is configured to be positioned with an external measuring system or through a wavefront-based and/or intensity-based alignment with respect to the image plane of the optical imaging system.

7. The measuring apparatus as claimed in claim 1,
configured to form measurement channels through the optical imaging system which pass through the image plane at respective ones of the field points to be measured, wherein the change in relative position comprises a relative translational movement of the intensity detector in relation to the optical imaging system in a lateral direction with respect to an optical axis of the optical imaging system by at least a spacing between two adjacent measurement channels.

8. The measuring apparatus as claimed in claim 6,
wherein the evaluation device is configured to ascertain the telecentricity of the optical imaging system based on angle-resolved intensity distributions that are recorded at three different measurement positions which differ in relative displacement of the intensity detector with respect to the optical imaging system along a translational degree of freedom.

9. The measuring apparatus as claimed in claim 1,
wherein the change in relative position comprises a relative rotational movement of the intensity detector in relation to the optical imaging system about an axis of rotation aligned with the direction of the optical axis.

10. The measuring apparatus as claimed in claim 1,
wherein the evaluation device is configured to determine a respective associated pupil image position from the recorded angle-resolved intensity distributions for each of the relative positions at all measured field points.

11. The measuring apparatus as claimed in claim 10,
wherein the respective determined pupil image position comprises a displacement value of the relevant pupil image vis-à-vis an associated standard pupil image, which corresponds to a pupil image free from telecentricity, in at least one coordinate direction.

12. The measuring apparatus as claimed in claim 10,
wherein the evaluation device is configured to determine the displacement values by evaluating a system of equations containing the determined pupil image positions.

13. The measuring apparatus as claimed in claim 10,
wherein the evaluation device is configured to provide a determination of the pupil image positions with sub-pixel accuracy respectively in relation to a pixel resolution of the intensity detector.

14. The measuring apparatus as claimed in claim 10,
wherein the evaluation device is configured to provide a determination of the pupil image positions with an edge fit of the recorded intensity distributions.

15. The measuring apparatus as claimed in claim 14,
wherein the respective edge fit is implemented based on intensity distributions averaged over different measurement positions of the intensity detector.

16. The measuring apparatus as claimed in claim 10,
wherein the evaluation device is configured to convert the determined pupil image positions into telecentricity angles of the optical imaging system.

17. The measuring apparatus as claimed in claim 1,
wherein the evaluation device is configured to determine the numerical aperture at each of the field points from the recorded angle-resolved intensity distributions and to determine the telecentricity in accordance with the numerical aperture at each of the field points.

18. The measuring apparatus as claimed in claim 3,
configured to measure the measurement channels in a partially serial manner through displacement of the intensity detector.

19. A microlithographic projection exposure apparatus comprising a projection lens and a measuring arrangement as claimed in claim 1, for measuring a telecentricity of the projection lens.

20. A method for measuring a telecentricity of an optical imaging system, comprising:
irradiating an object plane of the optical imaging system with measurement radiation,
arranging an intensity detector comprising multiple non-overlapping detection portions in a plane offset from an image plane of the optical imaging system and acquiring angle-resolved intensity distributions present at at least two field points in the image plane from respective detection portions of the intensity detector,
changing a relative position of the intensity detector with respect to the optical imaging system in at least one rigid body degree of freedom, to set different measurement positions, and acquiring the intensity distribution of at least one of the field points before and after the change in relative position from two different ones of the non-overlapping detection portions of the intensity detector, and
ascertaining the telecentricity of the optical imaging system based on angle-resolved intensity distributions, recorded at the different measurement positions, at each of the at least two field points.
